(19) United States
(12) Patent Application Publication
(10) Pub. No.: US 2026/0066030 A1
(43) Pub. Date: Mar. 5, 2026

(54) SEMICONDUCTOR MEMORY DEVICE AND MEMORY REPAIR METHOD

(71) Applicant: Renesas Electronics Corporation, Tokyo (JP)

(72) Inventors: Yudai KAWANO, Tokyo (JP); Tomonori SASAKI, Tokyo (JP); Takeshi UEKI, Tokyo (JP)

(21) Appl. No.: 19/297,394

(22) Filed: Aug. 12, 2025

(30) Foreign Application Priority Data
Aug. 27, 2024 (JP) 2024-145120

(51) Int. Cl. G11C 29/44

(52) U.S. Cl. CPC G11C 29/4401

(57) ABSTRACT

Provided is a memory repair circuit including a memory built-in self-test (MBIST) circuit that generates a repair code on the basis of a test result in a market, a register that holds the generated repair code, and a path for transmitting the repair code to a repair circuit. The memory repair circuit may include a logical circuit that performs a logical operation of a repair code generated at the time of mass production and a repair code based on the test result in the market.

### CROSS-REFERENCE TO RELATED APPLICATIONS

The disclosure of Japanese Patent Application No. 2024-145120 filed on Aug. 27, 2024 including the specification, drawings and abstract is incorporated herein by reference in its entirety.

### BACKGROUND

The present disclosure relates to a memory repair circuit and a memory repair method.

There is disclosed a technique listed below.
[Patent Document 1] Japanese Unexamined Patent Application Publication No. 2013-149308

Patent Document 1 discloses a memory repair method.

### SUMMARY

However, there is no description of relieving a memory in a market. Therefore, an object of the present disclosure is to provide a memory repair circuit or the like capable of relieving a memory in a market.

Other problems and novel features will become apparent from the description of the present specification and the accompanying drawings.

According to an embodiment, a memory repair circuit that generates a repair code on the basis of a test result in a market and holds the generated repair code is provided.

According to the above-described embodiment, a memory repair circuit or the like capable of relieving a memory in a market can be provided.

### BRIEF DESCRIPTION OF THE DRAWINGS

FIG. 1 is a block diagram illustrating a configuration of a memory repair circuit according to an embodiment.

FIG. 2 is a flowchart of a memory repair method according to the embodiment.

FIG. 3 is a block diagram illustrating a configuration of a field test control circuit according to the embodiment.

FIG. 4 is a flowchart of the memory repair method using the field test control circuit according to the embodiment.

FIG. 5 is a diagram illustrating a variation of a repair code holding method according to the embodiment.

FIG. 6 is a block diagram illustrating a configuration of a memory repair circuit according to a first embodiment.

### DETAILED DESCRIPTION

For clarity of description, the following description and drawings are omitted and simplified as appropriate. Each element illustrated in the drawings as a functional block that performs various processes can be configured by, for example, a central processing unit (CPU), a memory, and other circuits in terms of hardware, and implemented by a program loaded in the memory or the like in terms of software. Therefore, these functional blocks can be implemented by hardware, software operating on the hardware, or a combination thereof. Note that, in the drawings, the same elements are denoted by the same reference numerals, and redundant description is omitted as necessary.

The program described above can be stored using various types of non-transitory computer readable media and supplied to the computer. The non-transitory computer readable media include various types of tangible storage media. Examples of the non-transitory computer readable media include a magnetic recording medium (for example, a flexible disk, a magnetic tape, or a hard disk drive), a magneto-optical recording medium (for example, a magneto-optical disk), a CD-read only memory (ROM), a CD-R, a CD-R/W, and a semiconductor memory (for example, mask ROM, programmable ROM (PROM), erasable PROM (EPROM), flash ROM, and random access memory (RAM) ). The program may be supplied to the computer by various types of transitory computer readable media. Examples of the transitory computer readable media include electrical signals, optical signals, and electromagnetic waves. The transitory computer readable media can supply the program to the computer via a wired communication path such as an electric wire and an optical fiber, or a wireless communication path.

### Description of Related Memory Repair Circuit

In the following description, memory particularly refers to semiconductor memory device. Therefore, memory cells, repair circuits, and other peripheral circuits and elements may be implemented as components of a semiconductor integrated circuit. And, market particularly refers to a state in which semiconductor products are actually used after being shipped and installed in system products, or a state in which they are being prepared for such use.

A memory built-in self-test (MBIST) is performed before shipment. At that time, as a part of the memory test, a test for relieving a random access memory (RAM) is also performed in order to improve a yield. In recent years, a memory has been required to reduce a chip area in order to improve cost competitiveness. However, a memory with a reduced chip area has a small voltage margin and is likely to cause deteriorative defects in the market. Therefore, the inventor has found that a defect occurrence rate in the market can be reduced by performing memory repair also in the market.

### Description of Memory Repair Circuit According to Embodiment

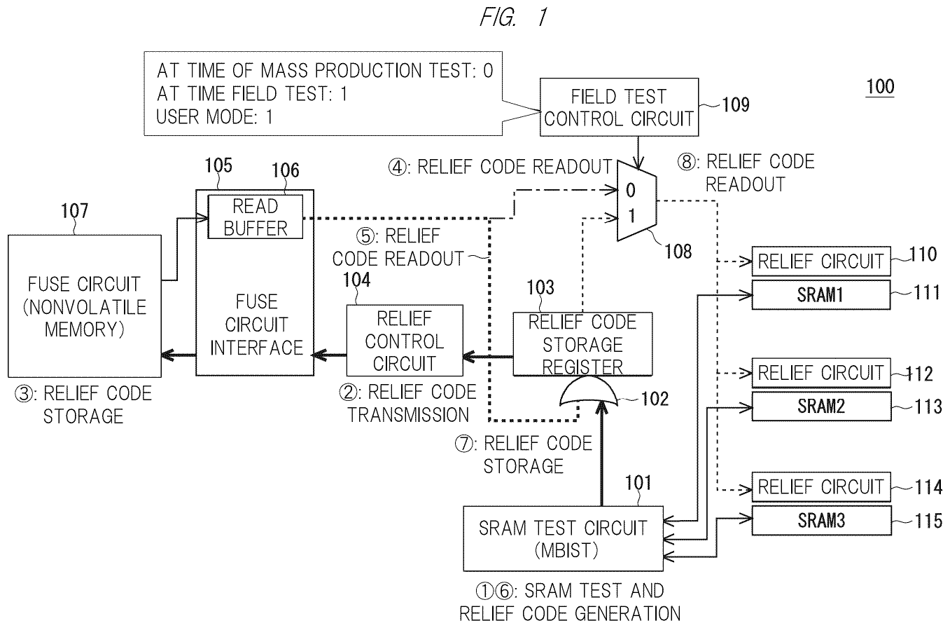

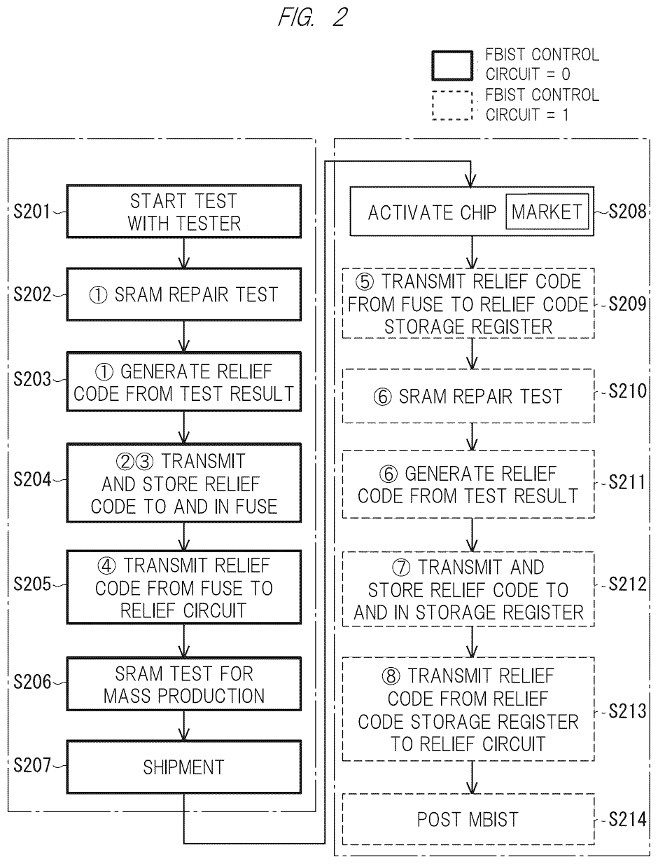

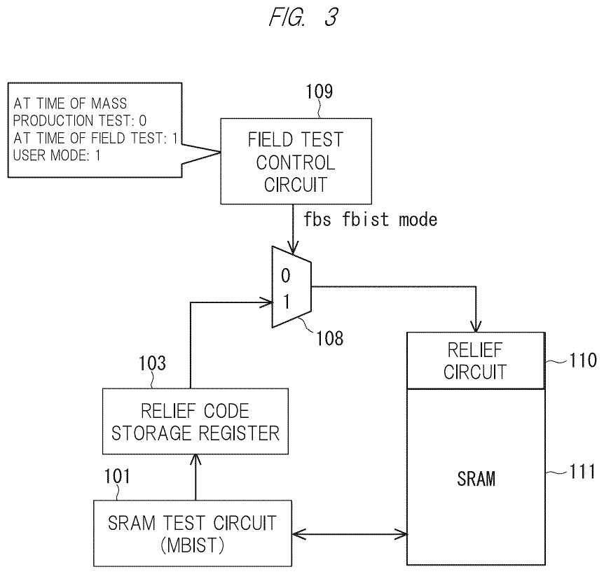

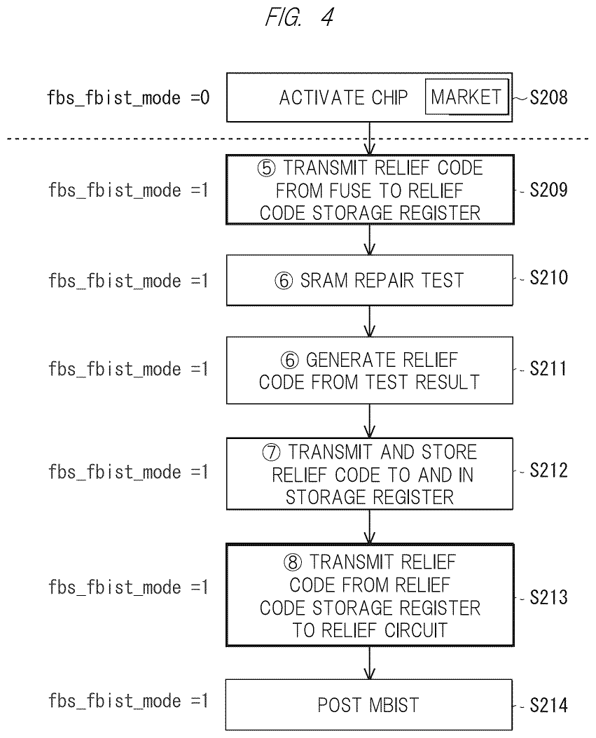

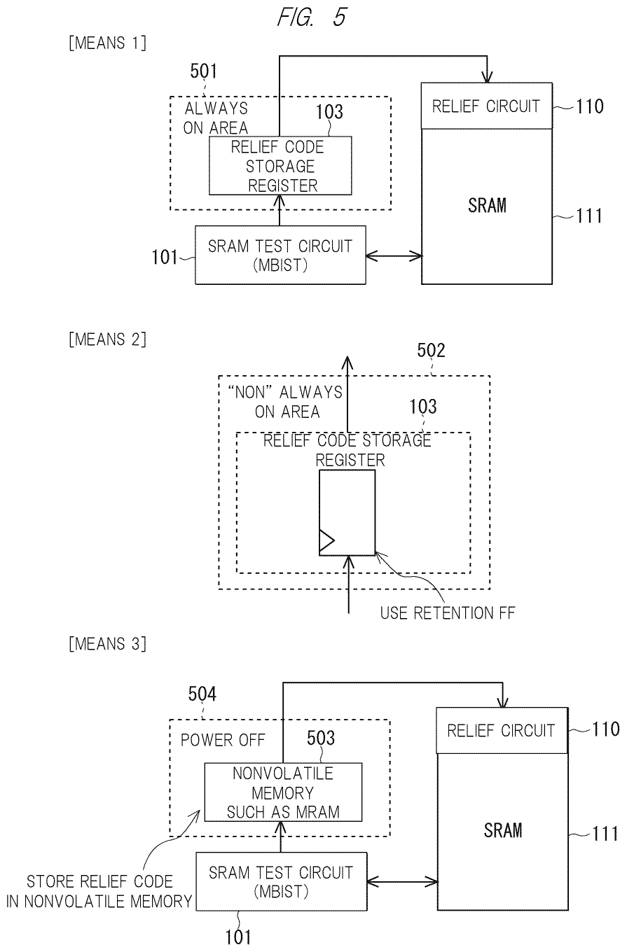

FIG. 1 is a block diagram illustrating a configuration of a memory repair circuit according to an embodiment. FIG. 2 is a flowchart of a memory repair method according to the embodiment. FIG. 3 is a block diagram illustrating a configuration of a field test control circuit according to the embodiment. FIG. 4 is a flowchart of a memory repair method using the field test control circuit according to the embodiment. FIG. 5 is a diagram illustrating a variation of a repair code holding method according to the embodiment. With reference to FIGS. 1 to 5, the memory repair circuit according to the embodiment is described. The memory repair circuit is a circuit in which a test circuit is incorporated in an LSI and a memory that is an internal circuit is tested.

As illustrated in FIG. 1, a memory repair circuit 100 includes an MBIST 101, which is a static random access memory (SRAM) test circuit, a logical circuit 102, a repair code storage register 103, a repair control circuit 104, a fuse circuit interface 105, and a fuse circuit (nonvolatile memory) 107. The memory repair circuit 100 further includes a control logical circuit 108, a field test control circuit 109, a repair circuit 110, an SRAM1 (111), a repair circuit 112, an SRAM2 (113), a repair circuit 114, and an SRAM3 (115).

A memory test at the time of mass production is described with reference to FIG. 2, too. The test with a tester is started (step S201). The MBIST 101 performs an SRAM repair test (step S202). The MBIST 101 tests a part of the SRAM1 (111), the SRAM2 (113), and the SRAM3 (115). Then, the MBIST 101 generates a repair code from a test result (step S203).

The repair code storage register 103 is a register that stores the repair code. The repair code storage register 103 is connected to the MBIST 101. The repair code storage register stores the repair code generated by the MBIST 101.

The repair control circuit 104 is connected to the repair code storage register 103. The repair control circuit 104 transmits the repair code to the fuse circuit interface 105 (step S204).

The fuse circuit interface 105 is connected to the repair control circuit 104. The fuse circuit interface 105 transmits the repair code to the fuse circuit 107 (step S204).

The fuse circuit 107 is connected to the fuse circuit interface 105. The fuse circuit 107 includes, for example, a nonvolatile memory. The fuse circuit 107 stores the transmitted repair code (step S204).

The repair code stored in the fuse circuit 107 is transmitted to the control logical circuit 108 via a read buffer 106 of the fuse circuit interface 105 (step S205). The read buffer 106 is connected to the control logical circuit 108. The control logical circuit 108 is connected to the repair circuit 110, the repair circuit 112, and the repair circuit 114. The repair code read by the control logical circuit 108 is transmitted to the repair circuit 110, the repair circuit 112, and the repair circuit 114. On the basis of the transmitted repair code, an SRAM test for mass production is performed using the relieved SRAM (step S206). According to the repair code, redundant bits provided in the SRAM are used, and the SRAM test for mass production is performed. Finally, it is shipped (step S207). Specifically, for example, access to a faulty memory area is replaced with access to an alternative area according to the repair code. This method involves allocating a redundant area in the memory in advance, and when a fault is found in part of the original memory area, a change in the wiring pattern or access address may be performed. As a result, the memory is logically reconfigured without the need for external entities accessing the memory to sense it. This is called repair.

Next, a test in the market is described. Here, the market refers to a state in which semiconductor products are actually used after being shipped and installed in system products, or a state in which they are being prepared for such use. A chip is activated and is prepared for starting the test (step S208). Subsequent steps may be performed not only in a test step but also in a state of being used by a user. Next, the repair code is transmitted from the fuse circuit 107 to the repair code storage register 103 (step S209). The fuse circuit 107 is connected to the control logical circuit 108 and the repair code storage register 103. A purpose of transmitting the repair code of the fuse circuit 107 to the storage register is that test conditions are different between the test at the time of mass production and the test in the market, and a failure to be detected is different. Next, the MBIST 101 performs the SRAM repair test (step S210). Then, the MBIST 101 generates the repair code from a test result (step S211).

The MBIST 101 transmits the repair code to the repair code storage register 103 (step S212). The repair code generated by the MBIST 101 and the repair code stored in the fuse circuit 107 are subjected to a logical operation by the logical circuit 102, and the repair code is stored in the repair code storage register 103 (step S212). In other words, the logical circuit 102 performs the logical operation of the repair code generated at the time of mass production and the repair code based on the test result in the market. When the repair codes at the time of mass production of the SRAM1 (111), the SRAM2 (113), and the SRAM3 (115) are 1011 (with repair), 0000 (without repair), and 0000 (without repair), and the repair codes in the market are 1011, 0000, and 1001, for example, the SRAM1 (111) is not updated, the SRAM2 (113) is not relieved, and the SRAM3 (115) is relieved.

The repair code is transmitted from the repair code storage register 103 to the repair circuit (step S213). That is, the repair code storage register 103 includes a path for transmitting the repair code to the repair circuit. Finally, the SRAM1 (111), the SRAM2 (113), and the SRAM3 (115) are relieved in the market by the MBIST.

The field test control circuit 109 selects and switches between modes at the time of mass production test and at the time of test in the market. Here, the market has the same meaning as a field, and the market may be read as the field. As illustrated in FIG. 3, 0 is set at the time of mass production test, and 1 is set at the time of field test. As illustrated in FIG. 2, at the time of mass production test, a field built-in self-test (FBIST) control circuit is set to 0, and memory repair at the time of mass production is performed. At the time of market test, the FBIST control circuit is set to 1, and memory repair in the market is performed. As illustrated in FIG. 4, fbs_fbist_mode is set to 0 when the chip is activated in the market, which is an initial value. From step S209 to step S214, while the memory repair is performed in the market, fbs_fbist_mode is set to 1. In a user mode used by the user, fbs_fbist_mode is set to 1.

An example in which the repair code storage register holds the repair code is described with reference to FIG. 5. Means 1 is to arrange the repair code storage register in an always-powered-on area 501. The always-power-on area in which power supply is retained even when the semiconductor device is in the power-off state. A value is held by always inputting power to the register.

Means 2 is that the repair code storage register itself is arranged in a “non” always powered on area 502, but a retention flip-flop circuit is used. A flip-flop of a substantial part required to operate at a high speed includes a transistor having a low threshold voltage. That is, although a speed is high, a leakage current is large. A retention flip-flop is a flip-flop having a high threshold voltage and a low leakage current. A retention flip-flop is arranged next to this normal flip-flop, and an output of the flip-flop having a low threshold voltage is input to the retention flip-flop immediately before the power is cut off. Other than the retention flip-flop stops operating, and when the power is turned on again, the retention flip-flop returns data to the flip-flop having the low threshold voltage. In this manner, the repair code storage register 103 can hold the repair code.

Means 3 is to use a nonvolatile memory 503 such as an MRAM that can hold a value in a power-off area 504 in the repair code storage register 103. The repair code storage register 103 can hold the repair code even if the power is turned off by storing the repair code in the nonvolatile memory 503.

With the configuration described above, it is possible to provide the memory repair circuit and the memory repair method capable of relieving the memory in the market. Therefore, it is possible to relieve the deteriorative failure, and the defect occurrence rate in the market decreases. A test time is determined depending on the user in the test in the market, and under such a situation, the use of this embodiment provides the repair code without passing through the fuse circuit, so that the test time is shortened.

### Description of Memory Repair Circuit According to First Embodiment

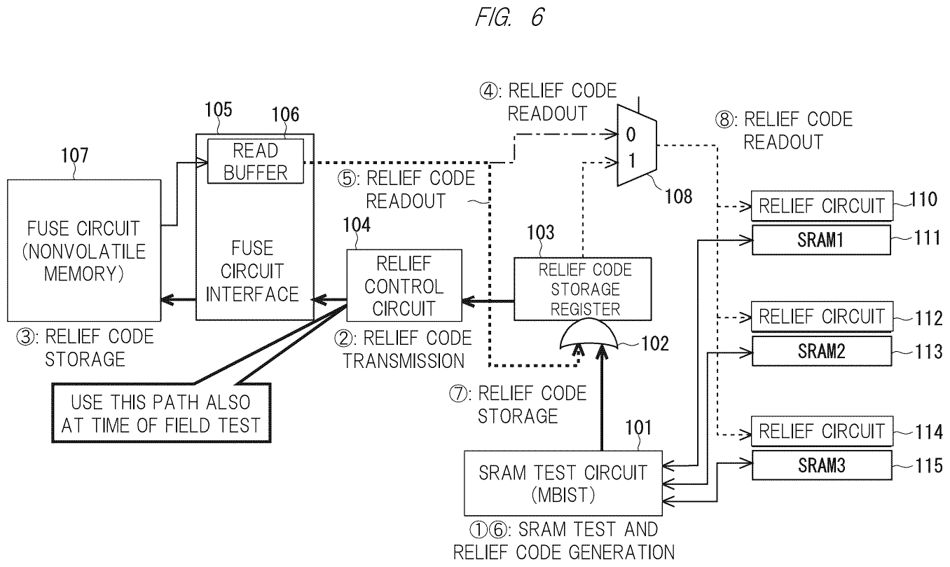

FIG. 6 is a block diagram illustrating a configuration of a memory repair circuit according to a first embodiment. With reference to FIG. 6, the memory repair circuit according to the first embodiment is described.

As illustrated in FIG. 6, after performing an SRAM test in a market (step S210), an MBIST 101 may generate a repair code and transmit the repair code to a fuse circuit 107. The repair code is written in the fuse circuit. The repair code is transmitted from the fuse circuit 107 to a repair code storage register 103, and the repair code is stored in the repair code storage register 103 (step S212). The repair code is transmitted from the repair code storage register to the repair circuit (step S213), and a memory is relieved.

With the configuration described above, it is not required that the repair code storage register 103 be in an always powered on area.

Although the invention made by the present inventor has been specifically described on the basis of the embodiments, the present invention is not limited to the embodiments described above, and it goes without saying that various modifications can be made without departing from the gist of the present invention.

1. A semiconductor device comprising:
a memory circuit,
a memory built-in self-test (MBIST) circuit that generates a repair code based on a test result in market use;
a register that holds the generated repair code; and
a repair circuit configured to repair a logical structure of the memory circuit by replacing accesses to a faulty memory area with an alternative area in accordance with the repair code.

2. The semiconductor device according to claim 1, further comprising a logical circuit that performs a logical operation of a repair code generated at a time of mass production and the repair code based on the test result in the market use.

3. The semiconductor device according to claim 1, further comprising a fuse circuit that holds a repair code generated at a time of mass production,
wherein the repair circuit comprises a control logical circuit that selects a signal from the fuse circuit and a signal from the register.

4. The semiconductor device according to claim 3, further comprising a field test control circuit that selects the control logical circuit.

5. The semiconductor device according to claim 1, wherein the register is arranged in an always-power-on area in which power supply is retained even when the semiconductor device is in a power-off state.

6. The semiconductor device according to claim 1, wherein the register comprises a retention flip-flop circuit.

7. The semiconductor device according to claim 1, wherein the register comprises a nonvolatile memory.

8. The semiconductor device according to claim 3, wherein the repair code based on the test result in the market use is written in the fuse circuit.

9. A memory repair method comprising:
generating a repair code according to a test result in a market use by an MBIST circuit;
holding the generated repair code by a register; and
transmitting the repair code to a repair circuit.

10. The memory repair method according to claim 9 comprising performing a logical operation of a repair code generated at a time of mass production and the repair code based on the test result in the market use by a logical circuit.

11. The memory repair method according to claim 9 comprising:
holding a repair code generated at a time of mass production by a fuse circuit; and
selecting a signal from the fuse circuit and a signal from the register by a control logical circuit.

12. The memory repair method according to claim 11 comprising selecting the control logical circuit by a field test control circuit.

13. The memory repair method according to claim 9, wherein the register is arranged in an always-power-on area in which power supply is retained even when a memory device is in a power-off state.

14. The memory repair method according to claim 9, wherein the register comprises a retention flip-flop circuit.

15. The memory repair method according to claim 9, wherein the register comprises a nonvolatile memory.

16. The memory repair method according to claim 11, wherein the repair code based on the test result in the market use is written in the fuse circuit.
